(19) United States
(12) Patent Application Publication
(10) Pub. No.: US 2016/0197224 A1
(43) Pub. Date: Jul. 7, 2016

(54) SEALING RESIN, SEMICONDUCTOR DEVICE, AND PHOTOCOUPLER

(71) Applicant: Kabushiki Kaisha Toshiba, Tokyo (JP)

(72) Inventors: Tetsuya Muranaka, Fukuoka-ken (JP); Kayo Inoue, Fukuoka-ken (JP); Yuichi Ikedo, Fukuoka-ken (JP)

(21) Appl. No.: 15/071,260

(22) Filed: Mar. 16, 2016

Related U.S. Application Data
(63) Continuation of application No. 14/751,687, filed on Jun. 26, 2015.
Application No. 14/751,687 is a division of application No. 14/202,521, filed on Mar. 10, 2014, now abandoned.

(30) Foreign Application Priority Data
Sep. 13, 2013 (JP) 2013-191198

(51) Int. Cl. H01L 31/167; H01L 23/29; H01L 23/31; H01L 25/16

(52) U.S. Cl. CPC H01L 31/167; H01L 25/167; H01L 23/295; H01L 23/3135

(57) ABSTRACT

A semiconductor device includes: a sealing resin and a semiconductor element. The sealing resin includes a base resin and a curing agent. The base resin includes isocyanuric acid having an epoxy group. The curing agent includes an acid anhydride having an acid anhydride group. A mole ratio of the acid anhydride group to the epoxy group is not less than 0.67 and not more than 0.8. A semiconductor element is covered with the sealing resin.

### CROSS-REFERENCE TO RELATED APPLICATIONS

This application is a continuation of application Ser. No. 14/751,687, filed Jun. 26, 2015 which is a divisional of application Ser. No. 14/202,521, filed Mar. 10, 2014 and is based upon and claims the benefit of priority from Japanese Patent Application No. 2013-191198, filed on Sep. 13, 2013; the entire contents of each are incorporated herein by reference.

### FIELD

Embodiments described herein relate generally a sealing resin, a semiconductor device and a photocoupler.

### BACKGROUND

When using a semiconductor device in a high-temperature/high-humidity environment, it is desirable to increase the heat resistance and moisture resistance of the sealing resin.

In such a semiconductor device in which a semiconductor element is sealed with a resin, the reliability may decrease in the case where peeling occurs between the semiconductor element and the sealing resin or between multiple resins, etc.

Also, in the case where the semiconductor element includes a light emitting element and/or a light receiving element, the characteristics of the semiconductor device may undesirably change because the peeling of the resin causes the light intensity to change.

### BRIEF DESCRIPTION OF THE DRAWINGS

FIG. 1A is a graph in which the adhesion strength is measured for mole ratios of the acid anhydrous group included in the curing agent to the epoxy group included in the base resin and FIG. 1B is a schematic view showing the method for measuring the adhesion strength;

FIG. 2 is a photocoupler sealed with the sealing resin according to the first embodiment;

FIG. 3A is a graph of the fluctuation ratio (%) of the optical coupling efficiency for the PCT for a mole ratio of 0.57,

FIG. 3B is a graph of the fluctuation ratio (%) of the optical coupling efficiency for the PCT for a mole ratio of 0.67, FIG. 3C is a graph of the fluctuation ratio (%) of the optical coupling efficiency for the PCT for a mole ratio of 0.8 and FIG. 3D is a graph of the fluctuation ratio (%) of the optical coupling efficiency for the PCT for a mole ratio of 1;

FIG. 4 is a SEM photograph in which region H of FIG. 2 is enlarged;

FIG. 5 is a schematic cross-sectional view of a photocoupler using the sealing resin of the first embodiment;

FIG. 6 is a graph showing the fluctuation ratio of the optical coupling efficiency for a high temperature exposure test at 150° C. for the photocoupler shown in FIG. 5;

FIG. 7 is a graph showing the fluctuation ratio of the optical coupling efficiency for a high temperature exposure test at 150° C. for a photocoupler according to a comparative example;

FIG. 8A is a schematic cross-sectional view in the case where the filler weight % is lower for the inner resin of a first modification of the photocoupler; FIG. 8B is a schematic cross-sectional view in the case where the filler weight % is lower for the outer resin of the double molded structure; and FIG. 8C is a schematic cross-sectional view of the resin layer interface;

FIG. 9 is a schematic view of a second modification of the photocoupler;

FIG. 10 is a chemical formula of 1,3,5-tris(2,3-epoxypropyl)isocyanuric acid;

FIG. 11 is a chemical formula of isomethyltetrahydrophthalic anhydride; and

FIG. 12 is a chemical formula of a polymer of 1,3,5-tris(2,3-epoxypropyl)isocyanuric acid and isomethyltetrahydrophthalic anhydride.

### DETAILED DESCRIPTION

In general, according to one embodiment, a semiconductor device includes: a sealing resin and a semiconductor element. The sealing resin includes a base resin and a curing agent. The base resin includes isocyanuric acid having an epoxy group. The curing agent includes an acid anhydride having an acid anhydride group. A mole ratio of the acid anhydride group to the epoxy group is not less than 0.67 and not more than 0.8. A semiconductor element is covered with the sealing resin.

Embodiments of the invention will now be described with reference to the drawings.

The sealing resin according to a first embodiment includes a base resin including isocyanuric acid having an epoxy group, and a curing agent including an acid anhydride.

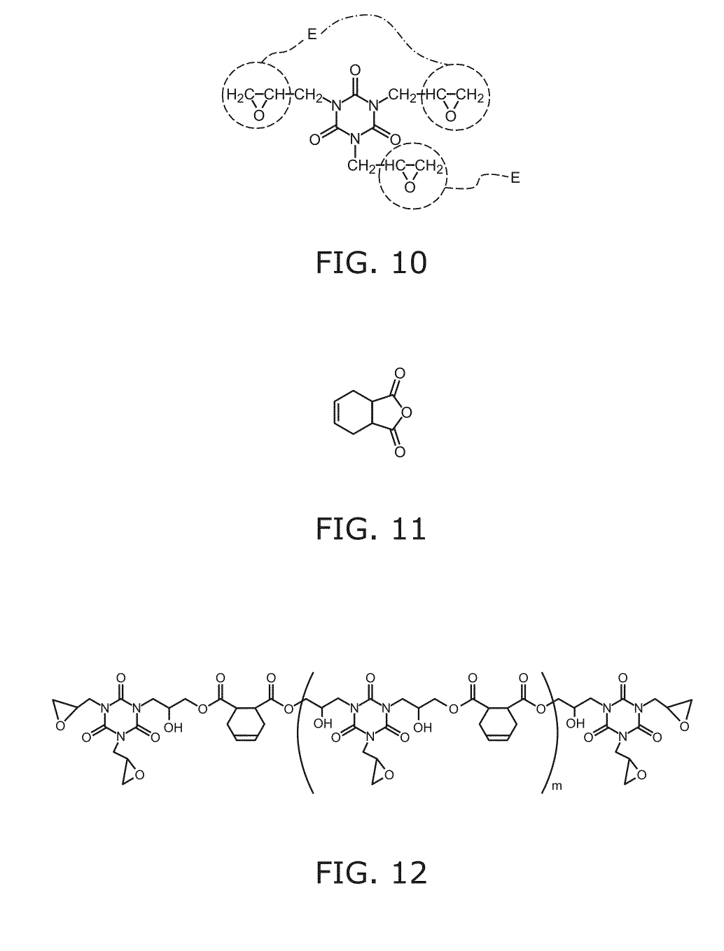

The base resin may be, for example, 1,3,5-tris(2,3-epoxypropyl)isocyanuric acid having three epoxy groups E, etc., as represented by a chemical formula in FIG. 10.

The acid anhydride may be, for example, isomethyltetrahydrophthalic anhydride, etc., as represented by a chemical formula in FIG. 11.

A cured material which is a polymer of 1,3,5-tris(2,3-epoxypropyl)isocyanuric acid and isomethyltetrahydrophthalic anhydride may be, for example, as represented by a chemical formula in FIG. 12.

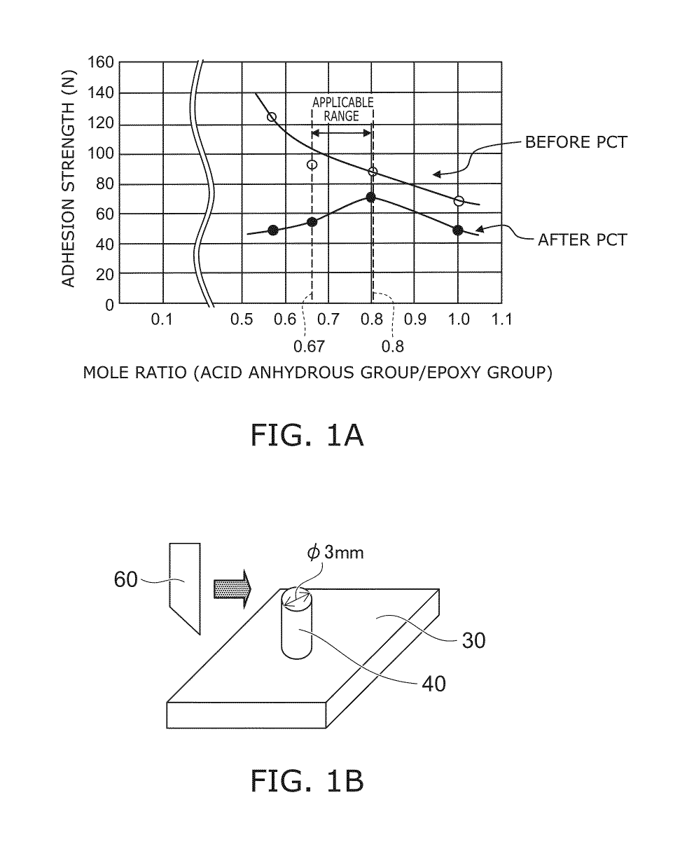

FIG. 1A is a graph in which the adhesion strength is measured for mole ratios of the acid anhydrous group included in the curing agent to the epoxy group included in the base resin; and FIG. 1B is a schematic view showing the method for measuring the adhesion strength.

Although the sealing resin includes 1,3,5-tris(2,3-epoxypropyl)isocyanuric acid as the base resin and isomethyltetrahydrophthalic anhydride as the curing agent, the materials are not limited thereto. The vertical axis is the adhesion strength (N); and the horizontal axis is the mole ratio of the acid anhydrous group to the epoxy group. The white circles are the adhesion strength prior to the PCT (the Pressure Cooker Test); and the black circles are the adhesion strength after the PCT.

As shown in FIG. 1B, a sealing resin 40 according to the first embodiment is bonded to the surface of the chip of a semiconductor element 30 such as a light receiving element, etc. A tool 60 that is mounted to a load sensor (not shown) is brought into contact with the sealing resin and is pressed against the sealing resin. The shear strength, which is the load at which the sealing resin 40 breaks, is determined. The surface of the semiconductor element 30 normally includes a protective layer such as a polyimide resin, a Si oxide film, etc. The adhesion strength substantially does not depend on the material properties of the protective layer.

The adhesion strength prior to the PCT has a decreasing trend as the mole ratio increases to 0.57, 0.67, 0.8, and 1. On the other hand, the adhesion strength after the PCT has a peak value between the mole ratios of 0.6 and 1. It is favorable for the adhesion strength after the PCT to be 55 N or more. It is desirable for the adhesion strength prior to the PCT to be 90 N or more.

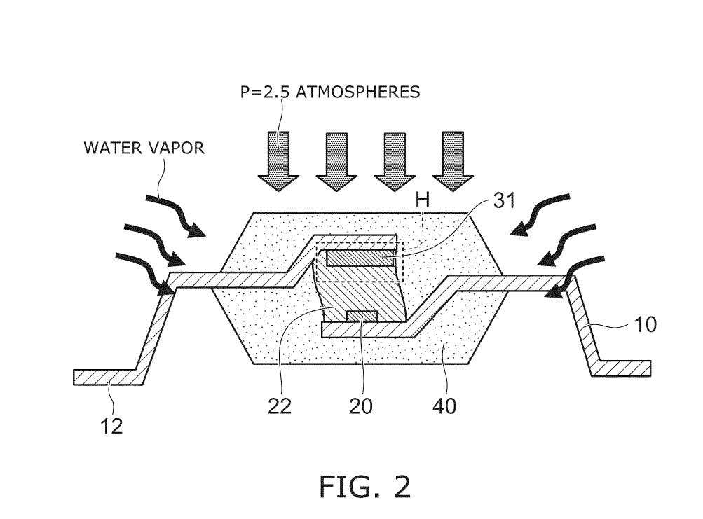

FIG. 2 is a photocoupler sealed with the sealing resin according to the first embodiment.

A light emitting element 20 such as an LED (light emitting diode) that is bonded to a first lead 10 opposes a light receiving element 31 that is bonded to a second lead 12. The light emitting element 20 is covered with a potting resin 22 for encapsulation. The sealing resin 40 is transparent to infrared light.

The light emitting element 20 is caused to emit light; and a prescribed voltage is supplied to the light receiving element 31. The fluctuation ratio of the optical coupling efficiency can be determined by, for example, measuring the current of the light receiving element 31 when starting the PCT, after 20 hours, and after 200 hours. It is favorable for the semiconductor device to be shielded such that external light does not enter the light receiving element 31.

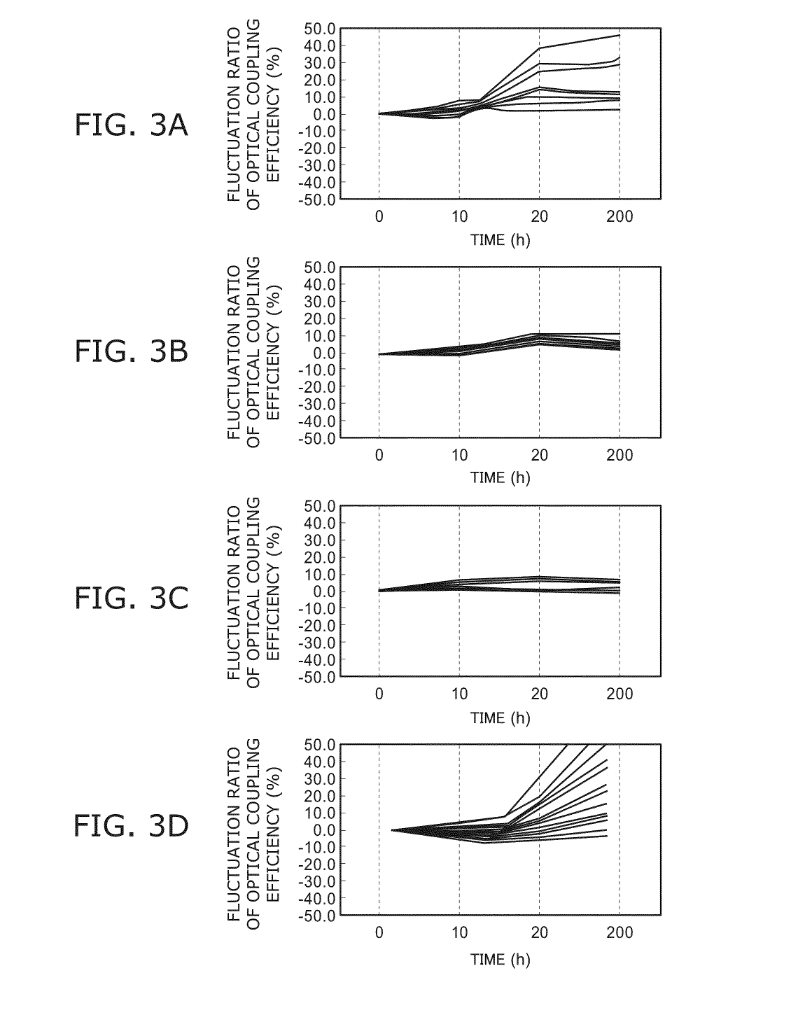

FIG. 3A is a graph of the fluctuation ratio (%) of the optical coupling efficiency for the PCT for a mole ratio of 0.57; FIG. 3B is a graph of the fluctuation ratio (%) of the optical coupling efficiency for the PCT for a mole ratio of 0.67; FIG. 3C is a graph of the fluctuation ratio (%) of the optical coupling efficiency for the PCT for a mole ratio of 0.8; and FIG. 3D is a graph of the fluctuation ratio (%) of the optical coupling efficiency for the PCT for a mole ratio of 1.

The fluctuation ratio (%) of the optical coupling efficiency is calculated by performing the PCT for a constant amount of time, subsequently measuring the current flowing on the light receiving side after returning the conditions to normal temperature and pressure, and by dividing the measured current by the current flowing on the light receiving side that was measured at normal temperature and pressure prior to starting the PCT.

In the PCT, for example, the semiconductor device such as the photocoupler is in an atmosphere of saturation vapor pressure at 2.5 atmosphere and 127° C.; and the water vapor is forced into the resin. Then, at 100° C. and at least 1 atmosphere, the water vapor molecules in the resin move freely; and the resin volume increases. Then, at 1 atmosphere and 25° C., the water vapor becomes water; the resin volume decreases; and starting points for peeling occur. Then, when reflow is performed at 260° C., gaps occur due to steam explosions, etc., when the water that causes the starting points for the peeling changes into water vapor.

In the case where the mole ratio is 1 or more, ring-opening of the acid anhydride that is unreacted in the PCT occurs because the water absorption rate is high; the acid anhydride dissolves into water; and peeling occurs easily between the sealing resin 40 and the surface of the semiconductor element 30.

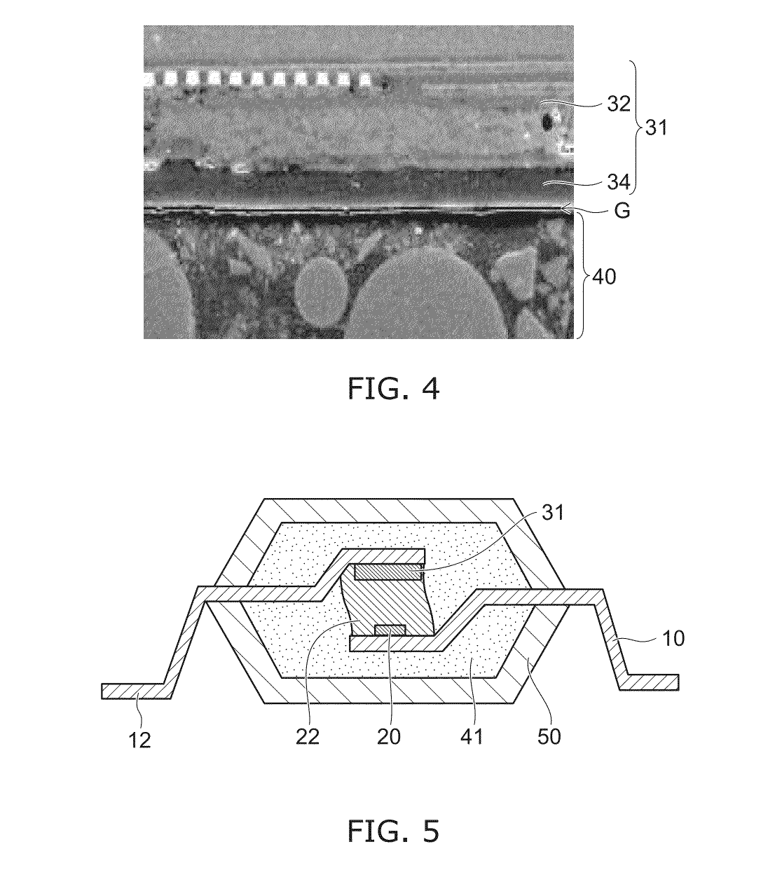

FIG. 4 is a SEM (Scanning Electron Microscope) photograph in which region H of FIG. 2 is enlarged. A space G occurs due to the peeling between the sealing resin 40 and the surface of the light receiving element 31. Therefore, the optical coupling efficiency changes.

As a result, for example, as shown in FIG. 3D (when the mole ratio is 1), the fluctuation ratio of the optical coupling efficiency starts to increase abruptly at 20 hours. On the other hand, in the case where the mole ratio is low, i.e., 0.57, as shown in FIG. 3A, the curing agent is insufficient; and the epoxy group is excessive. Therefore, the adhesion strength after the PCT decreases markedly; and the peeling between the sealing resin 40 and the surface of the light receiving element 31 occurs easily.

Conversely, in FIG. 3B in which the mole ratio is 0.67 and in FIG. 3C in which the mole ratio is 0.8, the decrease of the adhesion strength between the sealing resin 40 and the light receiving element 31 is suppressed; and the peeling can be suppressed. In other words, in the sealing resin 40, it is favorable for the mole ratio of the acid anhydrous group included in the curing agent to the epoxy group included in the base resin to be set to be not less than 0.67 and not more than 0.8. Peeling does not occur between the potting resin 22 and the light emitting element 20 in the PCT.

The sealing resin 40 of the first embodiment is not limited to being used in the photocoupler and is widely applicable to light emitting devices, light receiving devices, and semiconductor devices.

FIG. 5 is a schematic cross-sectional view of a photocoupler using the sealing resin of the first embodiment.

In the photocoupler, the light emitting element 20 that is bonded to the first lead 10 opposes the light receiving element 31 that is bonded to the second lead 12. The light emitting element 20 is covered with the potting resin 22 for encapsulation.

The photocoupler of the embodiment has a double molded structure including an inner resin 41 and an outer resin 50. The inner resin 41 is made of the sealing resin 40 according to the first embodiment and is transparent to light from visible light to infrared light. The outer resin 50 is provided around the inner resin 41, one end portion of the first lead 10, and one end portion of the second lead 12. The outer resin 50 is light-shielding at the wavelengths of the light emitted by the light emitting element 20 (and natural light from the outside). The other end portion of the first lead 10 and the other end portion of the second lead 12 protrude from the outer resin 50 to form connection terminals to the outside. Because the inner resin 41 and the outer resin 50 are molded bodies, the quality stabilizes around the light emitting element; downsizing of the photocoupler is possible; and high suitability for mass production is possible.

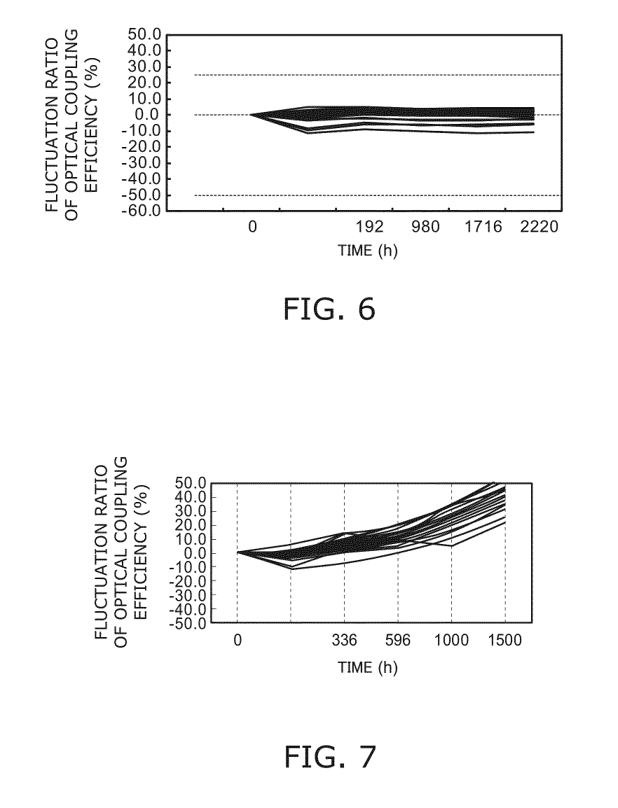

FIG. 6 is a graph showing the fluctuation ratio of the optical coupling efficiency for a high temperature exposure test at 150° C. for the photocoupler shown in FIG. 5.

The vertical axis is the fluctuation ratio (%) with respect to the initial value of the optical coupling efficiency; and the horizontal axis is the time. The fluctuation ratio of the optical coupling efficiency is low even after 2000 hours has elapsed.

Also, the fluctuation ratio of the transmittance of the inner resin 41 which is the sealing resin of the first embodiment is low, i.e., not more than 25% after exposure to an atmosphere of 200° C. for 90 hours.

FIG. 7 is a graph showing the fluctuation ratio of the optical coupling efficiency for a high temperature exposure test at 150° C. for a photocoupler according to a comparative example.

The inner resin includes a base resin of an orthocresol novolac (OCN) resin having one epoxy group per unit, and a curing agent including a phenolic resin. A quinone structure occurs in the phenolic resin due to oxidization; and the phenolic resin discolors. Therefore, after exposing for 90 hours in an atmosphere of 200° C., the transmittance decreases to 42% to 51% of the initial value. As a result, after 1500 hours has elapsed in an atmosphere of 150° C., the fluctuation ratio of the optical coupling efficiency is as much as 20% to 50%.

Conversely, in the photocoupler shown in FIG. 5, the peeling of the resin in the PCT can be suppressed; and the discoloration of the inner resin 41 due to the oxidization can be reduced. Therefore, the fluctuation ratio of the optical coupling efficiency in a high-temperature environment can be reduced; and the reliability can be increased.

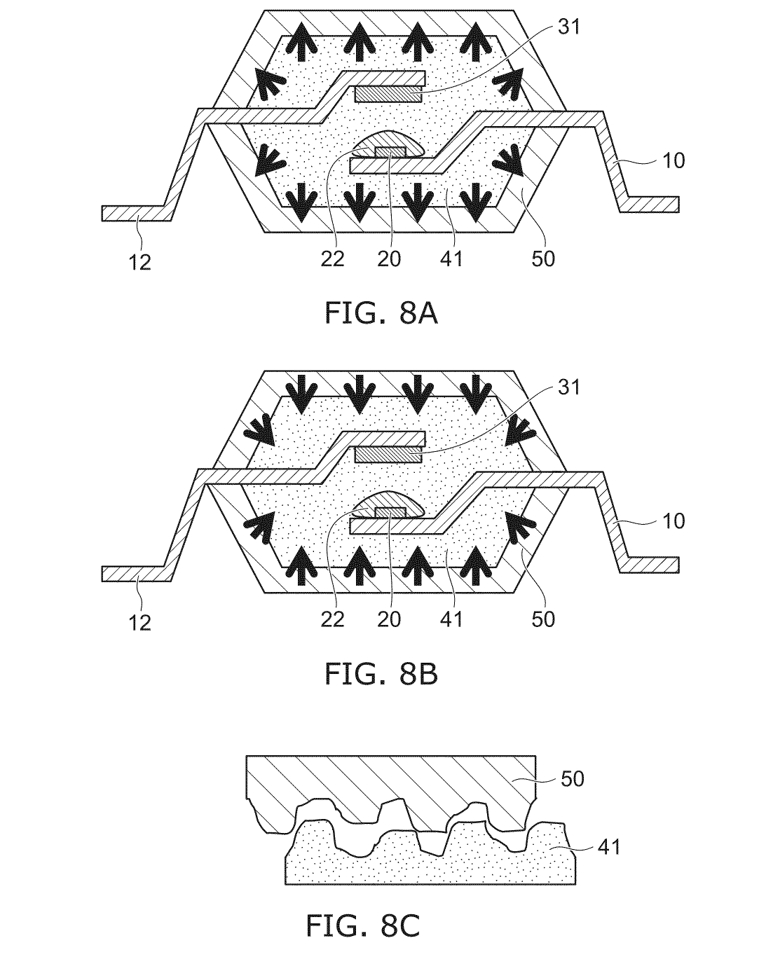

FIG. 8A is a schematic cross-sectional view in the case where the filler weight % is lower for the inner resin of a first modification of the photocoupler; FIG. 8B is a schematic cross-sectional view in the case where the filler weight % is lower for the outer resin of the double molded structure; and FIG. 8C is a schematic cross-sectional view of the resin layer interface.

The first modification has a double molded structure including the inner resin 41, and the outer resin 50 provided around the inner resin 41. The inner resin 41 is the sealing resin 40 of the first embodiment. The outer resin 50 is a polymer of an orthocresol novolac resin as a base resin and a phenol novolac resin as a curing agent.

An inorganic filler can be contained in the inner resin 41 and the outer resin 50. The filler that is contained may be, for example, a silica including fused silica and/or crystalline silica, alumina, silicon nitride, aluminum nitride, etc. The filler configuration may be filament-like, spherical, etc.

A first filler is contained in the inner resin 41 in a first content ratio of not less than 60 weight % and not more than 85 weight %. A second filler is contained in the outer resin 50 in a second content ratio of not less than 60 weight % and not more than 85 weight %. Further, the difference between the first content ratio and the second content ratio is set to be not less than 5 weight % and not more than 12 weight %. The filler amount may be greater for either the first filler or the second filler. Also, the first filler and the second filler may have the same material properties and configurations.

In the case where the difference of the filler amounts is provided as shown in FIGS. 8A to 8C, a difference of the coefficients of linear expansion also occurs; and because the expansion is greater for the higher coefficient of linear expansion than for the lower coefficient of linear expansion in the after-cure (e.g., 2 hours at 190° C.) after the molding, at least one tightening at the recesses and protrusions of the interface occurs; and the adhesion strength between the inner resin 41 and the outer resin 50 increases. A difference of linear coefficients of thermal expansion of 0.3×10⁻⁵/° C. corresponds to a difference of filler amounts of about 5 weight %. A difference of linear coefficients of thermal expansion of 0.7×10⁻⁵/° C. corresponds to a difference of filler amounts of about 12 weight %. Table 1 shows an example of results of the adhesion strength measured for different filler amounts.

TABLE 1

| | | OUTER RESIN | |
|---|---|---|---|
| FILLER AMOUNTS | | 80 wt % | 75 wt % |
| INNER RESIN | 80 wt % | 79N | 102N |
| | 75 wt % | 85N | 93N |

For the double molded structure, peeling at the interface occurs when the adhesion strength between the inner resin 41 and the outer resin 50 is insufficient. The characteristics may fluctuate as resin cracks spread from the peeling region. Because the adhesion strength of the double molded structure is increased in the first modification, the peeling can be suppressed; and the characteristic fluctuation can be reduced.

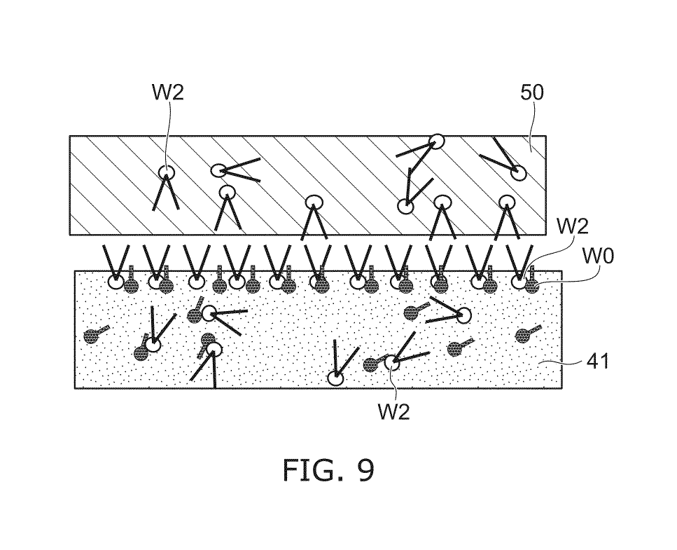

FIG. 9 is a schematic view of a second modification of the photocoupler.

The productivity can be increased for a molded resin body by adding wax to the molded resin body for easy release from the mold after the molding. Normally, the inner and outer resins include an external lubricant wax. However, in the case where the wax seeps out to form a film between the outer resin 50 and the inner resin 41, hydrogen bonding is obstructed; and the adhesion strength decreases. Table 2 shows examples of combinations of the waxes of the second modification.

TABLE 2

| | | ADHESION |
|---|---|---|
| INNER RESIN | OUTER RESIN | STRENGTH |
| EXTERNAL LUBRICANT | EXTERNAL | 33N |
| WAX | LUBRICANT WAX | |
| (INTERNAL + EXTERNAL) | EXTERNAL | 94N |
| LUBRICANT WAX | LUBRICANT WAX | |

In the embodiment, the inner resin 41 includes a mixture of an external lubricant wax W2 having low polarity and an internal lubricant wax W0 having high polarity; and the outer resin includes an external lubricant wax. The internal lubricant wax W0 having high polarity may include, for example, a fatty acid such as stearic acid, palmitic acid, behenic acid, arachidic acid, etc. The external lubricant wax W2 having low polarity may include, for example, a fatty acid ester such as a stearic acid ester, a palmitic acid ester, a behenic acid ester, an arachidic acid ester, etc. Thereby, the adhesion strength can be increased because, as shown in FIG. 9, the external lubricant wax W2 having low polarity attracts the internal lubricant wax W0 having high polarity; a portion of the internal lubricant wax W0 collects at the resin interface; and the internal lubricant wax

W0 on the inner resin 41 side attracts the external lubricant wax W2 on the outer resin 50 side of the resin interface. Therefore, the adhesion strength can be increased further to 94 N, etc

The sealing resin of the first embodiment can increase the strength of the adhesion to the surface of the semiconductor element. The semiconductor device in which the semiconductor element is sealed with the sealing resin can have less characteristic fluctuation even in a high-temperature/high-humidity environment. In particular, the photocoupler that includes the light emitting diode and the light receiving element can maintain a stable optical coupling efficiency in a high-temperature/high-humidity environment. Therefore, wide applications are possible in industrial devices, information devices, vehicles, etc.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A photocoupler, comprising:
an inner resin including a base resin and a curing agent, the base resin including isocyanuric acid having an epoxy group, the curing agent including an acid anhydride having an acid anhydride group, a mole ratio of the acid anhydride group to the epoxy group being not less than 0.67 and not more than 0.8, the inner resin containing an internal lubricant wax having high polarity and a fatty acid, and a second external lubricant wax having low polarity;
a light emitting element provided in the inner resin;
a light receiving element provided in the inner resin; and
an outer resin provided around the inner resin, the outer resin containing a first external lubricant wax having low polarity.

2. The photocoupler according to claim 1, wherein the isocyanuric acid includes 1,3,5-tris(2,3-epoxypropyl)isocyanuric acid, and the acid anhydride includes isomethyltetrahydrophthalic anhydride.

3. The photocoupler according to claim 1, wherein
a first inorganic filler is contained in the inner resin in a first content ratio of not less than 60 weight % and not more than 85 weight %,
a second inorganic filler is contained in the outer resin in a second content ratio of not less than 60 weight % and not more than 85 weight %, and
difference between the first content ratio and the second content ratio is not less than 5 weight % and not more than 12 weight %.

4. The photocoupler according to claim 3, wherein the first inorganic filler includes one selected from fused silica, crystalline silica, alumina, silicon nitride, and aluminum nitride, and the second inorganic filler includes one selected from fused silica, crystalline silica, alumina, silicon nitride, and aluminum nitride.

5. The photocoupler according to claim 3, wherein the first inorganic filler is one selected from filament-shaped and spherical, and the second inorganic filler is one selected from filament-shaped and spherical.

6. A photocoupler, comprising:
a inner resin including a base resin and a curing agent, the base resin including isocyanuric acid having an epoxy group, the curing agent including an acid anhydride having an acid anhydride group, a mole ratio of the acid anhydride group to the epoxy group being not less than 0.67 and not more than 0.8, the inner resin containing an internal lubricant wax having high polarity and including a fatty acid, and a second external lubricant wax having low polarity;
a light emitting element encapsulated with a potting resin, the potting resin being covered with the inner resin;
a light receiving element provided in the inner resin; and
an outer resin provided around the inner resin, the outer resin containing a first external lubricant wax having low polarity.

7. The photocoupler according to claim 6, wherein the isocyanuric acid includes 1,3,5-tris(2,3-epoxypropyl)isocyanuric acid, and the acid anhydride includes isomethyltetrahydrophthalic anhydride.

8. The photocoupler according to claim 6, wherein the first external lubricant wax includes a fatty acid ester, and the second external lubricant wax includes a fatty acid ester, and the internal lubricant wax includes a fatty acid.
